(19) United States
(12) Patent Application Publication
(10) Pub. No.: US 2021/0232796 A1
(43) Pub. Date: Jul. 29, 2021

(54) SCREEN ASSEMBLY, ELECTRONIC DEVICE, AND CONTROL METHOD OF SCREEN ASSEMBLY

(71) Applicant: VIVO MOBILE COMMUNICATION CO., LTD., Chang'an Dongguan (CN)

(72) Inventor: Chuan LIU, Chang'an Dongguan (CN)

(73) Assignee: VIVO MOBILE COMMUNICATION co., LTD., Chang'an Dongguan (CN)

(21) Appl. No.: 17/232,460

(22) Filed: Apr. 16, 2021

Related U.S. Application Data
(63) Continuation of application No. PCT/CN2019/111220, filed on Oct. 15, 2019.

(30) Foreign Application Priority Data
Oct. 16, 2018 (CN) 201811202707.5

(51) Int. Cl. G06K 9/00; H01L 27/32

(52) U.S. Cl. CPC G06K 9/0004; G06K 9/00228; H01L 27/3227; H01L 27/3234

(57) ABSTRACT

A screen assembly, an electronic device, and a control method of a screen assembly are provided. The screen assembly includes: a display panel; an infrared light source module, where the infrared light source module is arranged at the display panel, and the infrared light source module is configured to emit infrared light to one side of the display panel; and an infrared photosensitive module, where the infrared photosensitive module is arranged on the other side of the display panel, and the infrared photosensitive module is configured to receive reflected light formed after the infrared light emitted by the infrared light source module irradiates on a target object and is reflected to the infrared photosensitive module.

### CROSS-REFERENCE TO RELATED APPLICATIONS

This application is a continuation application of PCT Application No. PCT/CN2019/111220 filed on Oct. 15, 2019, which claims priority to Chinese Patent Application No. 201811202707.5, filed in China on Oct. 16, 2018, disclosures of which are incorporated herein by reference in their entireties.

### TECHNICAL FIELD

This disclosure relates to the field of electronic technologies, and in particular, to a screen assembly, an electronic device, and a control method of a screen assembly.

### BACKGROUND

As users demand for aesthetic appearance and visual perception of high screen-to-body ratio terminals, full-screen mobile terminals have gradually become a development trend and are gradually going to the market. To improve overall screen-to-body ratios and aesthetics of mobile terminals, solutions such as in-screen fingerprint recognition and facial recognition have gradually emerged.

One of research and development ideas for in-screen fingerprint recognition in related art is to combine an organic light-emitting diode (OLED) screen to realize in-screen optical fingerprint recognition. This solution mainly uses an OLED emitting light source of the screen, and then performs fingerprint detection and recognition after emitted light is reflected by a finger to a sensor apparatus of a fingerprint module. However, because this solution uses OLED light to realize fingerprint recognition, its recognition rate is low, and it is difficult to emit light only to a fingerprint area, resulting in high power consumption. In addition, to increase a fingerprint recognition rate, it is necessary to increase light brightness of the OLED. As a result, power consumption is increased, and a user glares at strong light due to strong brightness of light, resulting in poor user experience.

In conclusion, in the related art, the solution of using an OLED screen to realize in-screen recognition has problems of a low recognition rate, high power consumption, and glare of strong light.

### SUMMARY

According to a first aspect, an embodiment of this disclosure provides a screen assembly, including:

a display panel;

an infrared light source module, where the infrared light source module is arranged at the display panel, and the infrared light source module is configured to emit infrared light to one side of the display panel; and an infrared photosensitive module, where the infrared photosensitive module is arranged on the other side of the display panel, and the infrared photosensitive module is configured to receive reflected light formed after the infrared light emitted by the infrared light source module irradiates on a target object and is reflected to the infrared photosensitive module.

According to a second aspect, an embodiment of this disclosure provides an electronic device, including the foregoing screen assembly.

According to a third aspect, an embodiment of this disclosure provides a control method of a screen assembly, applied to the foregoing screen assembly, and including:

detecting a trigger operation of invoking an infrared photosensitive module;

controlling, based on the trigger operation, an infrared light source module to start and emit infrared light; and

receiving, by the infrared photosensitive module, reflected light formed after the infrared light emitted by the infrared light source module irradiates on a target object and is reflected to the infrared photosensitive module, and generating detection information based on the reflected light.

### BRIEF DESCRIPTION OF DRAWINGS

To describe the technical solutions in the embodiments of this disclosure more clearly, the following briefly describes the accompanying drawings required for describing the embodiments of this disclosure. Apparently, the accompanying drawings in the following description show merely some embodiments of this disclosure, and a person of ordinary skill in the art may derive other drawings from these accompanying drawings without creative efforts.

FIG. 1 is a first schematic structural diagram of a screen assembly according to an embodiment of this disclosure;

FIG. 2 is a second schematic structural diagram of a screen assembly according to an embodiment of this disclosure;

FIG. 3 is a third schematic structural diagram of a screen assembly according to an embodiment of this disclosure;

FIG. 4 is a schematic cross-sectional view of the screen assembly shown in FIG. 3;

FIG. 5 is a fourth schematic structural diagram of a screen assembly according to an embodiment of this disclosure;

FIG. 6 is an diagram illustrating a scenario in which one emission light source is used for both in-screen fingerprint recognition and facial recognition in a screen assembly according to an embodiment of this disclosure; and

FIG. 7 is a schematic flowchart of a control method of a screen assembly according to an embodiment of this disclosure.

### DESCRIPTION OF EMBODIMENTS

To make the to-be-resolved technical problems, technical solutions, and advantages of this disclosure clearer, the following provides detailed descriptions with reference to the accompanying drawings and specific embodiments.

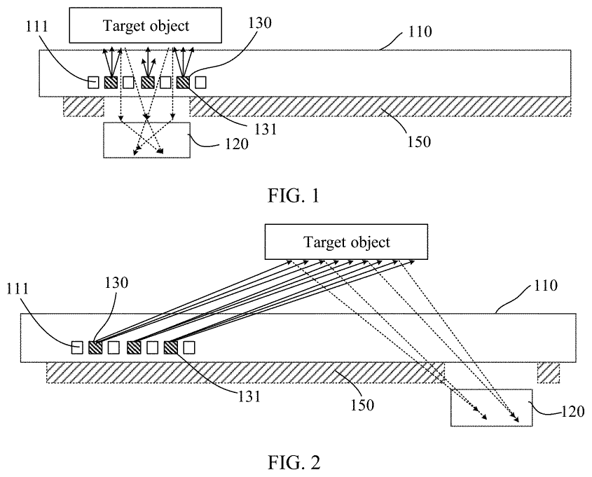

Referring to FIG. 1 and FIG. 2, an embodiment of this disclosure provides a screen assembly, which may include:

a display panel 110;

an infrared light source module 130, where the infrared light source module 130 is arranged at the display panel 110, and the infrared light source module 130 is configured to emit infrared light to one side of the display panel 110; and

an infrared photosensitive module 120, where the infrared photosensitive module 120 is arranged on the other side of the display panel 110, and the infrared photosensitive module is configured to receive reflected light formed after the infrared light emitted by the infrared light source module 130 irradiates on a target object and is reflected to the infrared photosensitive module 120.

In this embodiment of this disclosure, the infrared light source module 130 is arranged at the display panel 110 to provide infrared light to the infrared photosensitive module 120 arranged under the display panel 110 for the infrared photosensitive module to realize photosensitive detection. In this way, the purpose of in-screen recognition and detection by the infrared photosensitive module 120 can be achieved. In addition, using the infrared light source module 130 to provide infrared light can avoid the problems of high power consumption and glare of strong light due to direct full-screen emission of the display panel 110 in related art, thus reducing power consumption and increasing a detection and recognition rate of the infrared photosensitive module 120.

In this embodiment of this disclosure, the display panel 110 may be an OLED display panel. A basic structure of the display panel 110 is a sandwich-like structure formed by a thin, transparent, semiconductor-like indium tin oxide (ITO) connected to a positive electrode of a power source, and a metal cathode. This structure enables the infrared light source module 130 to be built in the display panel 110. Therefore, in an optional embodiment of this disclosure, the infrared light source module 130 may be arranged inside the display panel 110, thus enabling a compact structure, which is beneficial to reduce thickness of the screen assembly, making it light and thin.

Specifically, as shown in FIG. 1 and FIG. 2, the screen assembly starts the infrared light source module 130 and the infrared photosensitive module 120, to emit infrared light by using the infrared light source module 130. The infrared light emitted by the infrared light source module (the emitted infrared light is indicated by solid lines with arrows in FIG. 1 and FIG. 2) is projected to a target object to form reflected light (the reflected light may include emitted light and scattered light, as indicated by dotted lines with arrows in FIG. 1 and FIG. 2), and reflected to the infrared photosensitive module 120. The infrared photosensitive module 120 receives the reflected light and generates detection information based on the reflected light.

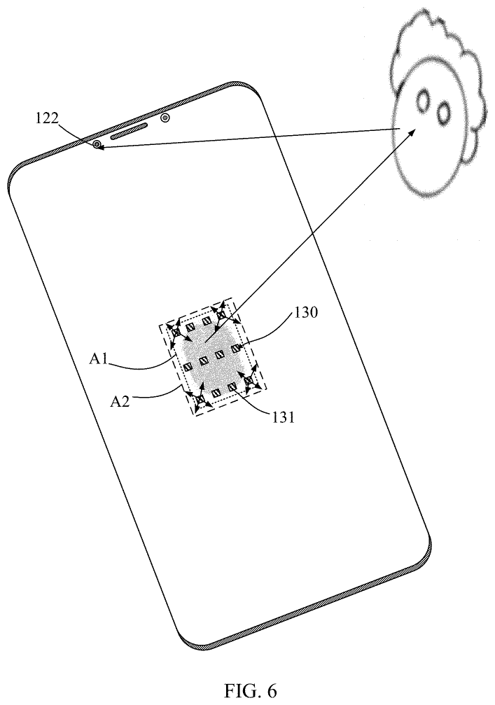

As shown in FIG. 4, the target object may be a finger, or, as shown in FIG. 6, the target object may be a human face, or the target object may be a photographed object, including scenes or other objects. Specific identification of the target object may be set based on a specific type or specific purpose of the infrared photosensitive module 120. Optionally, in this embodiment of this disclosure, the infrared photosensitive module 120 may be at least one of a fingerprint recognition module 121, a facial recognition module, and an infrared camera module 122.

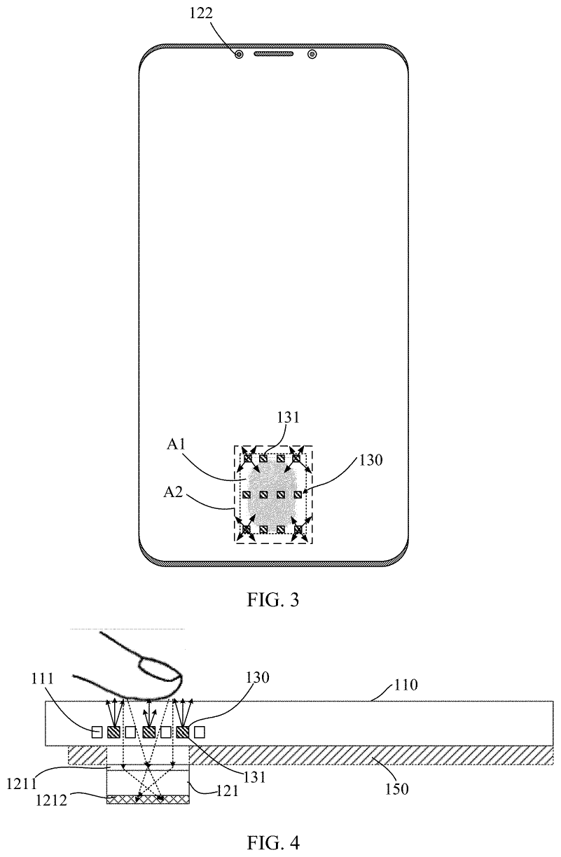

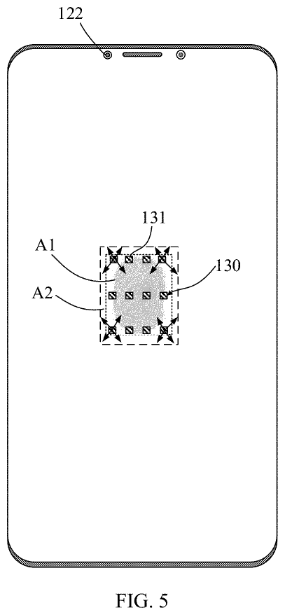

In an optional embodiment of this disclosure, the infrared photosensitive module 120 includes the fingerprint recognition module 121, and the fingerprint recognition module 121 corresponds to an arrangement position of the infrared light source module 130, where an irradiation area of the infrared light emitted by the infrared light source module 130 on the display panel 110 covers a fingerprint recognition area of the fingerprint recognition module 121. As shown in FIG. 3, FIG. 5, and FIG. 6, a block area designated A1 represents the fingerprint recognition area of the fingerprint recognition module 121, and a block area designated A2 represents the irradiation area of the infrared light emitted by the infrared light source module 130 on the display panel 110. In specific application, the fingerprint recognition area of the fingerprint recognition module 121 and the irradiation area of the infrared light emitted by the infrared light source module 130 on the display panel 110 may be set to various shapes, such as a circle, an ellipse, a heart shape, or a star shape, and may be specifically set according to an actual structure design, an effect requirement, or the like.

In this embodiment of this disclosure, the infrared light source module 130 may be built in the display panel 110, and the arrangement position of the infrared light source module 130 corresponds to the fingerprint recognition module 121, so that the infrared light source module 130 can provide infrared light for the fingerprint recognition module 121 for fingerprint recognition. In this way, the purpose of in-screen fingerprint recognition of the screen assembly can be achieved, and the infrared light source module 130 is configured to provide infrared light for the fingerprint recognition module 121. This can increase a fingerprint recognition rate and reduce power consumption, while avoiding the problem of glare of strong light in fingerprint recognition in related art.

Specifically, as shown in FIG. 4, when a finger touch is detected in the fingerprint recognition area, the screen assembly starts the infrared light source module 130 and the fingerprint recognition module 121, to emit infrared light through the infrared light source module 130. The infrared light emitted by the infrared light source module (the emitted infrared light is indicated by solid lines with arrows in FIG. 4) is projected to a target object to form reflected light (the reflected light may include emitted light and scattered light, as indicated by dotted lines with arrows in FIG. 4), and reflected to the fingerprint recognition module 121. The fingerprint recognition module 121 receives the reflected light and generates detection information based on the reflected light, and transmits the detection information to a processor for fingerprint recognition.

In an optional embodiment of this disclosure, as shown in FIG. 4, the fingerprint recognition module 121 may include an infrared fingerprint sensor 1211, to receive and process, through the infrared fingerprint sensor 1211, the emitted light projected by the infrared light source module 130 on the finger and then reflected by the finger, to realize fingerprint recognition. In addition, the fingerprint recognition module 121 may further include a lens 1212. The infrared light emitted by the infrared light source module 130 is projected on the finger and then reflected to form reflected light. The reflected light includes reflected rays or scattered rays, which pass through the lens 1212 and are refracted to the infrared fingerprint sensor 1211 according to the lens imaging principle, for receiving and processing by the infrared fingerprint sensor 1211.

As shown in FIG. 3, FIG. 5, and FIG. 6, in an optional embodiment of this disclosure, the infrared photosensitive module 120 includes an infrared camera module 122, configured to receive the reflected light formed by the emitted light irradiated by the infrared light source module 130 on the target object (photographed object) and process imaging. In this embodiment of this disclosure, the infrared camera module 122 can cooperate with the infrared light source module 130 to take photographs so as to realize infrared photography. In addition, in some embodiments, the infrared camera module 122 may be configured to realize a facial recognition function. Optionally, the infrared camera module 122 includes an infrared camera.

In some optional embodiments of this disclosure, the infrared photosensitive module 120 may include at least two of the fingerprint recognition module 121, the facial recognition module, and the infrared camera module 122. In this way, a plurality of types of infrared photosensitive modules 120 can use one emission light source.

As shown in FIG. 6, the infrared photosensitive module 120 includes both the fingerprint recognition module 121 and the infrared camera module 122, so that one emission light source is used for in-screen fingerprint recognition of the screen assembly and the infrared photography, thereby canceling an original infrared emitting component configured for infrared photography, saving device arrangement space, and reducing manufacturing costs.

Advantageously, as shown in FIG. 5, in this embodiment of this disclosure, a distance between the fingerprint recognition module 121 and the infrared camera module 122 is less than a preset value. The preset value may be specifically set based on setting requirements such as an emission angle and an emission distance of the emitted light of the infrared light source module 130. Herein, the setting of the preset value needs to at least ensure that the infrared light emitted by the infrared light source module 130 can irradiate an object within a predetermined range and the infrared camera module 122 can receive the emitted light formed by the infrared light irradiating on the photographed object. As shown in FIG. 5, in an example, the preset value may be ½ of a length of the screen assembly in a length direction. In this way, the fingerprint recognition area of the fingerprint recognition module 121 can be located in the middle of the screen assembly, thereby ensuring that the infrared camera module 122 cooperates with the infrared light source module 130 to implement photography, and facilitating recognition of user fingerprints, making it easier for the user to touch the fingerprint recognition area especially in the case of a large-sized screen assembly.

In an optional embodiment of this disclosure, as shown in FIG. 4, the infrared light source module 130 may include a plurality of infrared light emitting diodes 131, and the plurality of infrared light emitting diodes 131 are spaced apart from LED light emitting components of the display panel 110. In this embodiment of this disclosure, the plurality of infrared light emitting diodes 131 being spaced apart from the LED light emitting components can ensure that the infrared light emitting diodes 131 and the LED light emitting components do not affect each other. The function of the infrared photosensitive module 120 of the screen assembly can be ensured without affecting normal imaging of the display panel 110.

Optionally, in this embodiment of this disclosure, the plurality of infrared light emitting diodes 131 are spaced apart from pixel units 111 of the display panel 110, which facilitates a reasonable layout and can reduce space costs.

In this embodiment of this disclosure, the plurality of infrared light emitting diodes 131 in the display panel 110 may be specifically arranged according to an actual structure design, an infrared light emission effect, and the like. Optionally, in this embodiment of this disclosure, as shown in FIG. 3 and FIG. 5, the plurality of infrared light emitting diodes 131 are equidistantly arranged in a plurality of rows; or, the plurality of infrared light emitting diodes 131 are arranged into a matrix.

In addition, in this embodiment of this disclosure, a quantity and position arrangement of the plurality of infrared light emitting diodes 131 may alternatively be designed according to an implementation effect.

It can be understood that, in this embodiment of this disclosure, to increase receiving intensity of the infrared photosensitive module or to adapt to receiving intensity of different types of infrared photosensitive modules, it is only necessary to adjust emission intensity of the infrared light emitted by the infrared light source module 130, which can effectively avoid glare of strong light in related art, reduce power consumption, and prolong battery life.

In some embodiments of this disclosure, the infrared light source module 130 has a drive component connected to the plurality of infrared light emitting diodes 131, configured to start the plurality of infrared light emitting diodes 131 and adjust the emission intensity of the plurality of infrared light emitting diodes 131. The plurality of infrared light emitting diodes 131 can be better controlled by the drive component, and the plurality of infrared light emitting diodes 131 can be adjusted to emission intensity that suits actual needs, so as to meet various usage requirements of users.

It should be noted that the infrared light source module 130 can be set with emission intensity suiting different types of infrared photosensitive modules 120. To be specific, when the infrared photosensitive module 120 to be invoked is the fingerprint recognition module 121, the facial recognition module, or the infrared camera module 122, the drive component may adjust the emission intensity of the plurality of infrared light emitting diodes 131 to a suitable emission intensity value.

For example, if the infrared photosensitive module 120 includes the fingerprint recognition module 121, when the fingerprint recognition module 121 is invoked, the drive component adjusts the emission intensity of the plurality of infrared light emitting diodes 131 to a first preset intensity value; if the infrared photosensitive module 120 includes the facial recognition module, when the facial recognition module is invoked, the drive component adjusts the emission intensity of the plurality of infrared light emitting diodes 131 to a second preset intensity value; and if the infrared photosensitive module 120 includes the infrared camera module 122, when the infrared camera module 122 is invoked, the drive component adjusts the emission intensity of the plurality of infrared light-emitting diodes 131 to a third preset intensity value, where the first preset intensity value is less than the second preset intensity value, and the third preset intensity value is greater than or equal to the second preset intensity value.

In addition, in an embodiment of this disclosure, as shown in FIG. 1, an orthographic projection of at least a portion of the infrared photosensitive module 120 on the display panel 110 is within the range of an orthographic projection of the infrared light source module 130 on the display panel 110. For example, in an example, the infrared photosensitive module 120 includes the fingerprint recognition module 121. As shown in FIG. 4, an orthographic projection of the fingerprint recognition module 121 on the display panel 110 may be entirely or partially located within the range of an orthographic projection of the infrared light source module 130 on the display panel 110.

In another embodiment of this disclosure, as shown in FIG. 2, the orthographic projection of the infrared photosensitive module 120 on the display panel 110 is spaced apart from the orthographic projection of the infrared light source module 130 on the display panel 110. For example, in an example, the infrared photosensitive module 120 includes the infrared camera module 122, as shown in FIG. 3, FIG. 5, and FIG. 6, an orthographic projection of the infrared camera module 122 on the display panel 110 is spaced apart from an orthographic projection of the infrared light source module 130 on the display panel 110, where a spacing between the two may be set according to actual design requirements.

Referring to FIG. 1, FIG. 2, and FIG. 4, in an embodiment of this disclosure, the screen assembly may further include: a middle frame structure 150, which is attached to the display panel 110 and is arranged on the other side of the display panel 110 opposite an infrared light emitting direction of the infrared light source module 130. In this embodiment of this disclosure, the middle frame structure 150 is attached to the display panel 110 to support the display panel 110.

Optionally, in this embodiment of this disclosure, to ensure that the light reception of the infrared photosensitive module 120 is not affected, the middle frame structure 150 is provided with an opening corresponding to the infrared photosensitive module 120. It should be noted that the size of the opening should meet a preset requirement to at least ensure that the infrared photosensitive module 120 can receive the reflected or scattered reflected light in a predetermined area (for example, the fingerprint recognition area of the fingerprint recognition module 121).

In the screen assembly provided in this embodiment of this disclosure, the infrared light source module arranged at the display panel provides infrared light to the infrared photosensitive module arranged under the display panel for the infrared photosensitive module to realize photosensitive detection. In this way, the purpose of in-screen recognition and detection by the infrared photosensitive module can be achieved, and the problems of high power consumption and glare of strong light due to direct emission of the display panel in related art can be avoided, thus reducing power consumption and increasing a detection and recognition rate of the infrared photosensitive module.

In addition, an embodiment of this disclosure provides an electronic device, including the foregoing screen assembly.

The electronic device may further include a series of basic components such as a receiver, a speaker, a microphone, and a housing for accommodating various components, which are not further described in this embodiment of this disclosure.

In addition, in this embodiment of this disclosure, the electronic device may be a mobile phone or a tablet computer. Certainly, the electronic device is not limited to a mobile phone or a tablet computer, but may be a terminal device such as a laptop computer or a personal digital assistant (PDA).

In this embodiment of this disclosure, for the electronic device with the above-mentioned screen assembly, as the screen assembly can achieve the purpose of in-screen recognition and detection by the infrared photosensitive module, the problems of high power consumption and glare of strong light due to direct emission of the display panel in related art can be avoided, thus reducing power consumption and increasing a detection and recognition rate of the infrared photosensitive module. This allows the electronic device to implement an in-screen recognition function with an increased recognition rate and reduced power consumption, while avoiding the problem of glare of strong light in related art.

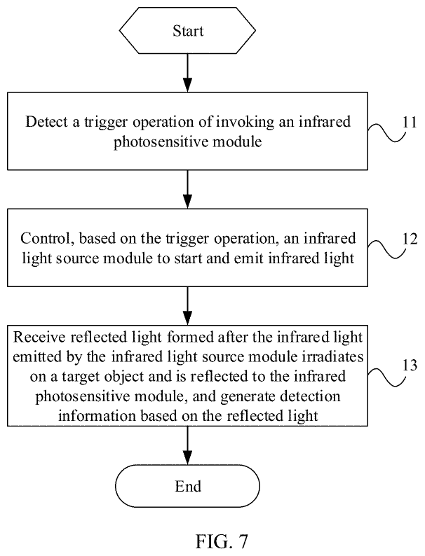

In addition, FIG. 7 is a schematic flowchart of a control method of a screen assembly according to an embodiment of this disclosure. This embodiment of this disclosure also provides a control method of a screen assembly, applied to the foregoing screen assembly. The control method of a screen assembly may include the following steps:

Step 11: Detect a trigger operation of invoking an infrared photosensitive module.

Step 12: Control, based on the trigger operation, an infrared light source module to start and emit infrared light.

Step 13: Receive reflected light formed after the infrared light emitted by the infrared light source module irradiates on a target object and is reflected to an infrared photosensitive module, and generate detection information based on the reflected light.

In this embodiment of this disclosure, after it is detected that a user triggers the infrared photosensitive module, the infrared light source module arranged at the display panel is controlled to start and emit infrared light, so that the infrared light is projected to the target object to form reflected light; and then the reflected light is received through the infrared photosensitive module, and detection information is generated based on the reflected light. In this way, the purpose of in-screen recognition and detection by the infrared photosensitive module can be achieved, and the problems of high power consumption and glare of strong light due to direct emission of the display panel in related art can be avoided, thus reducing power consumption and increasing a detection and recognition rate of the infrared photosensitive module.

In this embodiment of this disclosure, to better control and adjust the infrared light source module, the infrared light source module has a drive component, and the drive component is connected to a plurality of infrared light emitting diodes. In an optional embodiment of this disclosure, in step 12, the controlling, based on the trigger operation, the infrared light source module to start may include: sending a control instruction to the drive component of the infrared light source module based on the trigger operation, and by the driving component, starting the plurality of infrared light emitting diodes of the infrared light source module and adjusting emission intensity of the plurality of infrared light-emitting diodes.

Specifically, the infrared light source module can set emission intensity suiting different types of infrared photosensitive modules. To be specific, when the infrared photosensitive module to be invoked is a fingerprint recognition module, a facial recognition module, or an infrared camera module, the drive component may adjust the emission intensity of the plurality of infrared light emitting diodes to a suitable emission intensity value. In this embodiment of this disclosure, the sending a control instruction to the drive component of the infrared light source module based on the trigger operation, and by the drive component, starting the plurality of infrared light-emitting diodes of the infrared light source module and adjusting emission intensity of the plurality of infrared light emitting diodes may include: when the fingerprint recognition module is invoked, sending a first control instruction to the drive component of the infrared light source module based on the trigger operation, and by the drive component, starting the plurality of infrared light emitting diodes of the infrared light source module and adjusting the emission intensity of the plurality of infrared light emitting diodes to a first preset intensity value; when the facial recognition module is invoked, sending a second control instruction to the drive component of the infrared light source module based on the trigger operation, and by the drive component, starting the plurality of infrared light emitting diodes of the infrared light source module and adjusting the emission intensity of the plurality of infrared light emitting diodes to a second preset intensity value; and when the infrared camera module is invoked, sending a third control instruction to the drive component of the infrared light source module based on the trigger operation, and by the drive component, starting the plurality of infrared light emitting diodes of the infrared light source module and adjusting the emission intensity of the plurality of infrared light-emitting diodes to a third preset intensity value.

In the control method of a screen assembly provided in this embodiment of this disclosure, the purpose of in-screen recognition and detection by the infrared photosensitive module can be achieved, and the problems of high power consumption and glare of strong light due to direct emission of the display panel in related art can be avoided, thus reducing power consumption and increasing a detection and recognition rate of the infrared photosensitive module.

It should be understood that references to terms “an embodiment”, “one embodiment”, and “some embodiments” in the specification mean that specified features, structures, or characteristics related to the embodiment are included in at least one embodiment or example of this disclosure. Therefore, “in an embodiment”, “in one embodiment”, or “in some embodiments” appearing throughout the specification does not necessarily refer to a same embodiment. In addition, the elements, structures, or features described in an accompanying drawing or an embodiment of this disclosure may be combined with elements, structures, or features shown in one or more other accompanying drawings or embodiments in any suitable manner.

It should be noted that in one of more embodiments of this specification, the term “comprise”, “include”, or any other variant thereof is intended to cover a non-exclusive inclusion, so that a process, a method, an article, or an apparatus that includes a list of elements not only includes those elements but also includes other elements that are not expressly listed, or further includes elements inherent to such process, method, article, or apparatus. In absence of more constraints, an element preceded by “includes a . . . ” does not preclude the existence of other identical elements in the process, method, article, or apparatus that includes the element.

In this disclosure, unless otherwise specified and defined explicitly, the terms “mounted”, “interconnected”, “connected”, “fastened”, and “arranged” are to be interpreted broadly, for example, may be fixedly connected, or detachably connected, or integrated, may be mechanically connected or electrically connected, and may be directly connected or indirectly connected through an intermediate medium, or internally communicated between two elements or interacted between two elements. A person of ordinary skill in the art can understand specific meanings of these terms in this disclosure based on specific situations.

In addition, this disclosure may repeat reference numerals and/or letters in different embodiments or examples. This repetition is for the purpose of simplification and clarity, and does not in itself indicate any relationship between the various embodiments and/or arrangements discussed.

Moreover, in the embodiments of this disclosure, relational terms such as first and second are used only to differentiate one entity or operation from another entity or operation, and do not necessarily require or imply that any actual relationship or sequence exist between these entities or operations.

The embodiments of this disclosure are described above with reference to the accompanying drawings, but this disclosure is not limited to the foregoing implementations. The foregoing implementations are only illustrative rather than restrictive. Inspired by this disclosure, a person of ordinary skill in the art can still derive many variations without departing from the essence of this disclosure and the protection scope of the claims. All these variations shall fall within the protection of this disclosure.

What is claimed is:

1. A screen assembly, comprising:
a display panel;
an infrared light source module, wherein the infrared light source module is arranged at the display panel, and the infrared light source module is configured to emit infrared light to one side of the display panel; and
an infrared photosensitive module, wherein the infrared photosensitive module is arranged on the other side of the display panel, and the infrared photosensitive module is configured to receive reflected light formed after the infrared light emitted by the infrared light source module irradiates on a target object and is reflected to the infrared photosensitive module.

2. The screen assembly according to claim 1, wherein the infrared light source module is arranged inside the display panel.

3. The screen assembly according to claim 2, wherein the infrared light source module comprises:
a plurality of infrared light emitting diodes, wherein the plurality of infrared light emitting diodes are spaced apart from LED light emitting components of the display panel.

4. The screen assembly according to claim 3, wherein the plurality of infrared light emitting diodes are spaced apart from pixel units of the display panel.

5. The screen assembly according to claim 3, wherein the plurality of infrared light emitting diodes are spaced apart in a plurality of rows.

6. The screen assembly according to claim 3, wherein the plurality of infrared light emitting diodes are arranged into a matrix.

7. The screen assembly according to claim 3, wherein the infrared light source module has a drive component, wherein the drive component is connected to the plurality of infrared light emitting diodes and is configured to start the plurality of infrared light emitting diodes and adjust emission intensity of the plurality of infrared light emitting diodes.

8. The screen assembly according to claim 2, wherein an orthographic projection of at least a portion of the infrared photosensitive module on the display panel is within the range of an orthographic projection of the infrared light source module on the display panel.

9. The screen assembly according to claim 2, wherein an orthographic projection of the infrared photosensitive module on the display panel is spaced apart from an orthographic projection of the infrared light source module on the display panel.

10. The screen assembly according to claim 1, wherein the infrared photosensitive module is at least one of a fingerprint recognition module, a facial recognition module, and an infrared camera module.

11. The screen assembly according to claim 2, wherein the infrared photosensitive module is at least one of a fingerprint recognition module, a facial recognition module, and an infrared camera module.

12. The screen assembly according to claim 3, wherein the infrared photosensitive module is at least one of a fingerprint recognition module, a facial recognition module, and an infrared camera module.

13. The screen assembly according to claim 4, wherein the infrared photosensitive module is at least one of a fingerprint recognition module, a facial recognition module, and an infrared camera module.

14. The screen assembly according to claim 5, wherein the infrared photosensitive module is at least one of a fingerprint recognition module, a facial recognition module, and an infrared camera module.

15. The screen assembly according to claim 6, wherein the infrared photosensitive module is at least one of a fingerprint recognition module, a facial recognition module, and an infrared camera module.

16. The screen assembly according to claim 7, wherein the infrared photosensitive module is at least one of a fingerprint recognition module, a facial recognition module, and an infrared camera module.

17. The screen assembly according to claim 8, wherein the infrared photosensitive module is at least one of a fingerprint recognition module, a facial recognition module, and an infrared camera module.

18. An electronic device, comprising the screen assembly according to claim 1.

19. A control method of a screen assembly, applied to the screen assembly according to claim 1, and comprising:
detecting a trigger operation of invoking an infrared photosensitive module;
controlling, based on the trigger operation, an infrared light source module to start and emit infrared light; and
receiving, by the infrared photosensitive module, reflected light formed after the infrared light emitted by the infrared light source module irradiates on a target object and is reflected to the infrared photosensitive module, and generating detection information based on the reflected light.

20. The control method according to claim 12, wherein the controlling, based on the trigger operation, the infrared light source module to start comprises:
sending a control instruction to a drive component of the infrared light source module based on the trigger operation, and by the drive component, starting a plurality of infrared light emitting diodes of the infrared light source module and adjusting emission intensity of the plurality of infrared light-emitting diodes.
